(19) United States
(12) Patent Application Publication
(10) Pub. No.: US 2016/0013112 A1
(43) Pub. Date: Jan. 14, 2016

(54) Sensor System Comprising a Ceramic Housing

(71) Applicant: EPCOS AG, München (DE)

(72) Inventors: Jan Ihle, Grambach (AT); Bernhard Ostrick, Teltow (DE); Wolfgang Schreiber-Prillwitz, Fröndenberg (DE)

(21) Appl. No.: 14/766,405

(22) PCT Filed: Nov. 20, 2013
(86) PCT No.: PCT/EP2013/074300

§ 371 Date: Aug. 6, 2015

(30) Foreign Application Priority Data
Feb. 21, 2013 (DE) 10 2013 101 732.0

(51) Int. Cl. H01L 23/29; H01L 21/56

(52) U.S. Cl. CPC H01L 23/291; H01L 21/56

(57) ABSTRACT

A sensor system includes a sensor chip mounted on a mounting receptacle of a ceramic housing body. The housing body is shaped three-dimensionally and embodied monolithically and is formed by a ceramic material having a coefficient of thermal expansion which deviates from the coefficient of thermal expansion of the sensor chip by less than 30% in a temperature range of greater than or equal to −40° C. and less than or equal to 150° C.

This patent application is a national phase filing under section 371 of PCT/EP2013/074300, filed Nov. 20, 2013, which claims the priority of German patent application 10 2013 101 732.0, filed Feb. 21, 2013, each of which is incorporated herein by reference in its entirety.

### TECHNICAL FIELD

A sensor system comprising a sensor chip is specified.

### BACKGROUND

Constantly increasing requirements made of sensor systems such as, for example, acceleration sensors, rate-of-rotation sensors, magnetic sensors and pressure sensors with regard to accuracy and freedom from drift and with regard to mechanical robustness with respect to vibrations and shock require a special co-ordination of the sensitive elements, of the signal processing and of the housing components, wherein the latter hereinafter can also be designated as “packaging”. At the same time, it is necessary that such systems can be produced by cost-effective manufacture and have a reduced system complexity. In particular, the thermomechanical stress between the components constitutes a particular challenge.

In the prior art, stress-sensitive sensor elements are usually fixedly connected to the packaging only on one side and are mounted in a closed fashion in a cavity. In this case, the fixing is usually effected by adhesive bonding or soldering on one side.

For sufficient mechanical stability and for protection of the actual sensor against external influences and in order to avoid corrosion resulting from aggressive media, incorporation in a housing is implemented, which housing usually consists of plastic or of a material composite comprising plastic, ceramic, glass and/or metal. The housing can be embodied for example as a so-called cavity package, that is to say as a housing which has a mounting plate having a side wall extending circumferentially at the edge, which form a cavity. For the electrical connection, soldering contacts, plug contacts and/or line feeds are integrated into the housing. Such systems are suitably sealed using welds, solders, seals, potting materials and/or adhesives.

The prior art includes conventional housings such as plastic-encapsulated lead frame housings with sensitive elements bonded in by means of a soft adhesive and bonding wire contacting, HTCC cavity packages (HTCC: “high temperature co-fired ceramics”) for example based on aluminum oxide with sensitive elements softly adhesively bonded in and bonding wire contacting, HTCC cavity packages for example based on aluminum oxide with sensitive elements fixedly connected on the electrical leads (flip-chip bump technology), flat ceramic carriers for example composed of aluminum oxide with sensitive elements bearing on top, wherein a cavity is formed by a cover.

It can happen, however, that organic adhesive-bonding connections between the sensor elements and the packaging constitute a weak point with respect to long-term stability. Plastic housings are furthermore incompatible with alternative joining technologies such as, for example, welds and soldering connections. Therefore, most sensor systems in the prior art consist of material combinations which in turn require additional connections and make the systems very complex.

### SUMMARY

Embodiments of the invention specify a sensor system comprising a sensor chip in a housing.

In accordance with at least one embodiment, a sensor system, in particular a ceramic encapsulated sensor system, is provided.

In accordance with at least one embodiment, a sensor system comprises a sensor chip mounted on a mounting receptacle of a ceramic housing body. The housing body is produced from a ceramic material which is shaped three-dimensionally and embodied monolithically. Here and hereinafter, shaped three-dimensionally means that the housing body is not formed by a flat ceramic carrier, that is to say for example by a ceramic substrate in the form of a ceramic plate, but rather has a non-planar three-dimensional surface topography on the mounting side on which the sensor chip is mounted. In particular, the ceramic body has a three-dimensional surface structure on the side on which the sensor chip is applied, that is to say on the side having the mounting receptacle, in which surface structure for example the mounting receptacle is embodied as elevation or depression in a mounting area. Here and hereinafter, embodied monolithically means that the housing body is not produced from a composite assembly of a plurality of prefabricated ceramic parts, but rather is formed by an individual ceramic body which is embodied integrally and the three-dimensional shape of which is adapted to the requirements of the sensor system. That can in particular also mean that the housing body is embodied not only with a mounting receptacle for the sensor chip, but also with one or a plurality of further mounting receptacles for further sensor chips and/or for other electronic components such as, for example, signal processing chips and/or with mechanical fixing parts, such as, for example, elevations or depressions in the form of latching lugs or anchoring structures.

In particular, the housing body is that component of the sensor system on which the sensor chip and, if appropriate, further electronic components such as signal processing electronics, for example, are mounted. Here and hereinafter, mounting means that the sensor chip and, if appropriate, further electronic components are fixed directly, that means in each case by means of a connection material, on mounting receptacles of the housing body that are correspondingly provided for this purpose. The housing body can furthermore be the sole component and in particular the sole ceramic component of the sensor system on which the electronic and electrical components, that is to say for example chips, circuits and electrical connections, are mounted or applied.

With the aid of suitable production methods—described more thoroughly further below—for the housing body such as, for example, ceramic injection molding technology or the HTCC multilayer technique, even very complex ceramic housing designs adapted to sensor requirements can be produced precisely and reproducibly with a high mechanical strength. By virtue of the fact that the housing body is embodied monolithically with its three-dimensional shape, the complexity of the sensor system can furthermore be reduced. The reduction of the system complexity on account of the monolithic embodiment of the housing body in particular also as a result of a combination of a plurality of system components in a single component, said system components usually having to be joined together to form a composite assembly in the prior art, additionally also results in a saving in terms of material and costs.

In accordance with a further embodiment, the ceramic material of the housing body has a coefficient of thermal expansion which deviates from the coefficient of thermal expansion of the sensor chip by less than 30% in a temperature range of greater than or equal to −40° C. and less than or equal to 150° C. In other words, the coefficient of thermal expansion of the ceramic housing body is adapted to the coefficient of thermal expansion of the sensor chip. In particular, the coefficients of thermal expansion of the housing body and of the sensor chip can be adapted to one another and deviate from one another by less than 30% even in a temperature range of greater than or equal to −50° C. and less than or equal to 200° C. The smaller the difference between the coefficients of thermal expansion of the housing body and of the sensor chip, the lower the thermomechanical stresses that can occur in the sensor system between the sensor chip and the ceramic housing body. Therefore, it can be particularly advantageous if, in one of the temperature ranges mentioned, the coefficients of thermal expansion deviate from one another by less than 20% and preferably by less than 10%.

The sensor system described here is thus distinguished in particular by the fact that the coefficient of thermal expansion of the housing body is adapted to the coefficient of thermal expansion of the sensor chip. A suitable choice of the ceramic material for the housing body forming the packaging makes it possible to reduce thermomechanical stress that occurs as a result of temperature changes between the sensor chip and the housing body.

In accordance with a further embodiment the sensor chip is a silicon-based sensor chip. That means in particular that the sensor chip comprises silicon as basic material, functional regions being embodied and/or applied in and/or on said silicon.

In accordance with a further embodiment the sensor system is embodied as a so-called MEMS sensor system (MEMS: “micro-electro-mechanical system”). By way of example, the sensor system is embodied as an acceleration sensor, rate-of-rotation sensor, magnetic sensor or pressure sensor and has a sensor chip designed therefor, that is to say for example an acceleration sensor chip, rate-of-rotation chip, pressure sensor chip or magnetic sensor chip. If the sensor system is embodied as a magnetic sensor, the sensor chip can operate in particular for example according to the principle of the AMR effect (AMR: “anisotropic magnetoresistance”), the GMR effect (GMR: “giant magnetoresistance”) or the TMR effect (“tunnel magnetoresistance”) and can be designed for this purpose.

A suitable choice of the ceramic material of the housing body having a coefficient of thermal expansion that is in the range of the material of the sensor chip, that is to say in particular silicon, advantageously makes it possible to greatly reduce or even completely avoid thermally induced mechanical stresses that can lead to corruption of the sensor signal.

In accordance with a further embodiment the ceramic material comprises mullite, that is to say aluminum silicate. Furthermore, it may also be possible for the ceramic material of the housing body to comprise aluminum nitride, silicon carbide or silicon nitride. The ceramic housing body can also comprise a combination of the materials mentioned. Furthermore, the ceramic housing body can also consist of one or more of the ceramic materials mentioned. The advantage of the sensor system described here resides in the monolithic embodiment of the housing body with a suitable ceramic material such as that mentioned above. Consequently, a significantly improved thermomechanical adaptation of the housing body to the sensor chip is possible in comparison with the prior art.

In accordance with a further embodiment a signal processing chip is mounted on a further mounting receptacle of the housing body. Each of the mounting receptacles of the ceramic housing body can be embodied in a recessed fashion or else alternatively in an elevated fashion. The signal processing chip can in particular be provided for this purpose and embodied in such a way as to detect an electrical signal of the sensor chip and to process it further, such that a measured signal can be output via electrical connections of the sensor system. The signal processing chip can be embodied for example as an integrated circuit in the form of an individual chip or else in the form of a plurality of electronic components which are mounted using thick-film technology, for example. An electrical connection between the sensor chip and the signal processing chip can be provided by conductor tracks on and/or in the housing body and/or by bonding wire connections.

In accordance with a further embodiment the sensor chip is mounted over the whole area or partially directly on the mounting receptacle of the ceramic housing body by means of a flexible connection material. The flexible connection material can be formed in particular by a silicone adhesive or by an adhesive film without carrier or by a double-sided adhesive film with an inner carrier, that is to say a carrier lying between two adhesive films.

In accordance with a further preferred embodiment, the sensor chip is mounted directly on the mounting receptacle of the ceramic housing body by means of a rigid connection material. The rigid connection material can be formed for example by an epoxy resin adhesive or particularly preferably by a glass solder or a metallic solder.

The connection of the sensor chip to the ceramic housing body is particularly advantageously effected by means of a glass solder or a metal solder. It is thereby possible to avoid alterations of the sensor signal and of the mechanical connection between the sensor chip and the housing body such as are brought about by the ageing behavior of polymers. A solder connection, in particular a glass solder connection, can only be used if materials having similar coefficients of thermal expansion are used for the sensor chip and the ceramic housing body, that is to say, in the case of a silicon-based sensor chip, materials such as preferably mullite or else aluminum nitride, silicon nitride or silicon carbide for the housing body. It is only with the very similar coefficients of thermal expansion of the materials that are achievable as a result that, in the case of a fixed connection such as a glass solder connection, it is possible to avoid thermally induced strains in the sensor chip which might affect the sensor signal.

In order to produce the ceramic housing body, the three-dimensional and monolithic embodiment thereof can be effected by means of ceramic injection molding technology. The latter enables freely configurable geometries of the ceramic housing body, for example for shaping the integrated one or more mounting receptacles for the sensor chip and, if appropriate, for the signal processing chip. By virtue of the adaptable housing shape having the cavities or elevations for receiving the sensor and evaluation chips, it is possible to use different chips. Furthermore, a miniaturization of the sensor system is also possible.

In ceramic injection molding technology, a ceramic raw material, a so-called ceramic feedstock, which comprises or consists of a structural ceramic powder, advantageously mullite powder, aluminum nitride powder, silicon nitride powder or silicon carbide powder, and an organic binder, is injected into a corresponding mold. A green body produced in this way is then largely freed of the organic portion in a binder removal process, which can be in two stages (aqueous, thermal or catalytic) or in one stage (only thermal). The bodies from which the binder has been removed are subsequently sintered.

The advantage of ceramic injection-molded bodies resides in particular in the very precise embodiment of the housing dimensions, which enable simple and standardized mounting without additional system elements in conjunction with low thermal expansion, in a very high mechanical and chemical robustness and extreme long-term stability.

Alternatively, the production of the ceramic housing body in the three-dimensional and monolithic embodiment can be effected by means of HTCC multi-layer technology. In this case, the structuring of the housing for the mounting receptacles, for example, is effected by the stamping of ceramic sheets that are joined together to form a ceramic green body.

In order to form the finished ceramic housing body, a ceramic body produced by means of ceramic injection molding technology or HTCC multi-layer technology is sintered with a suitable temperature profile and in a suitable atmosphere, for example at 1500° C. to 1750° C. and Preferably at 1600° C. to 1750° C. in air in the case of mullite, depending on purity or proportion of sintering additive.

In accordance with a further embodiment the sensor system comprises electrical connections for the electrical connection at least of the sensor chip. Furthermore, the electrical connections can form the external connection of the sensor system. The electrical connections can be formed on and/or in the ceramic housing body and comprises one or more of the following elements: conductor tracks, wiring carriers, metallic vias, bonding wires.

The electrical connections can comprise or consist of conductor tracks, for example, which are applied directly on the ceramic housing body by means of metallization methods such as thick or thin film technology, for example. Advantageously, the mounting side of the housing body, on which the mounting receptacle for the sensor chip is situated, is embodied regionally in a planar fashion, such that conductor tracks can be deposited by means of cost effective screen printing technology or sputtering technology. Furthermore, a three-dimensional embodiment of the conductor tracks is also possible for example by means of pad printing or dispensing.

Furthermore, parts of the electrical connections can be led through the ceramic housing in the form of vias in order that conductor tracks fitted on both sides are electrically connected to one another.

Furthermore, the electrical connections can comprise a wiring carrier or be embodied as such or comprise or consist of a combination of a directly applied thick or thin film metallization with a wiring carrier. The wiring carrier can be electrically contacted externally by means of soldering connections, for example.

The wiring carrier can be a rigid or flexible printed circuit board, a lead frame or a lead frame enveloped at least partly with plastic. The wiring carrier can be directly mounted at the ceramic main body for example by latching, pressing or clamping into corresponding structures in the main body. Furthermore, the wiring carrier can also be fixed by means of direct soldering, for example soft soldering, hard soldering, glass soldering, active soldering, or adhesive bonding onto the main body and/or onto conductor tracks.

The sensor chip can be electrically connected at the electrical connections and/or at a signal processing chip for example by means of bonding wires or by direct mounting on conductor tracks.

In accordance with a further embodiment the sensor system comprises a cover fixed on the housing body above the sensor chip. The mounting side of the housing body, that is to say the side with the sensor chip, can be closed or encapsulated by the cover. The cover can comprise or be composed of plastic, metal or a ceramic material, for example.

In accordance with a further embodiment a wiring carrier which can form at least one portion of the electrical connections has cutouts through which parts of the housing body and/or of the cover engage or extend in order to lock or fix the wiring carrier.

In accordance with a further embodiment the housing body has cutouts into which corresponding parts of the cover and/or of a wiring carrier which forms at least one portion of the electrical connections engage or extend, thereby forming a mechanical locking for fixing the cover and/or the wiring carrier.

The cover can alternatively also be adhesively bonded or soldered on the housing body.

In accordance with a further embodiment the sensor chip and/or a signal processing chip are/is at least partly covered with a polymer potting. In particular, the sensor chip can be electrically contacted by means of bonding wire connections covered with the polymer potting. In particular, the polymer potting can form a protection of the covered parts and components with respect to the surroundings. For this purpose, the polymer potting can form a covering that forms at least part of an outer side of the pressure sensor system. As an alternative thereto, the polymer potting can also be arranged below a cover. In this case, the polymer potting can additionally or alternatively also cover parts of the housing body or of the electrical connections. The polymer potting can furthermore be arranged at a distance from the cover. By way of example, the cover can have a depression in which the sensor chip is arranged, wherein the polymer potting in this case does not completely fill the depression of the cover.

In accordance with a further embodiment the sensor system comprises a plurality of sensor chips on mounting receptacles of the ceramic housing body. Alternatively or additionally, a plurality of signal processing chips can also be provided.

In accordance with a preferred embodiment the sensor system comprises the following components: at least one silicon-based sensor chip, a ceramic housing body, and electrical connections. The ceramic housing body is embodied in monolithic embodiment and which has at least one mounting receptacle for the at least one sensor chip. The at least one sensor chip is directly connected to the ceramic housing body and electrical connections.

In further preferred embodiments, the sensor system additionally comprises one or a plurality of the following components: at least one signal processing chip which is arranged on at least one mounting receptacle of the housing body and which is preferably directly connected to the housing body, and a cover.

### BRIEF DESCRIPTION OF THE DRAWINGS

Further advantages, advantageous embodiments and developments will become apparent from the exemplary embodiments described below in association with the figures. In the figures:

FIG. 1 shows a schematic illustration of a sensor system in accordance with one exemplary embodiment,

FIGS. 2A to 2G show schematic illustrations of different views of a sensor system in accordance with a further exemplary embodiment, and

FIGS. 3A to 3F show schematic illustrations of different views of a sensor system in accordance with a further exemplary embodiment.

In the exemplary embodiments and figures, elements that are identical, of identical type or act identically may be provided in each case with the same reference signs. The illustrated elements and their size relationships among one another should not be regarded as true to scale; moreover, individual elements such as, for example, layers, component parts, components and regions may be illustrated with exaggerated size in order to enable better illustration and/or in order to afford a better understanding.

### DETAILED DESCRIPTION OF ILLUSTRATIVE EMBODIMENTS

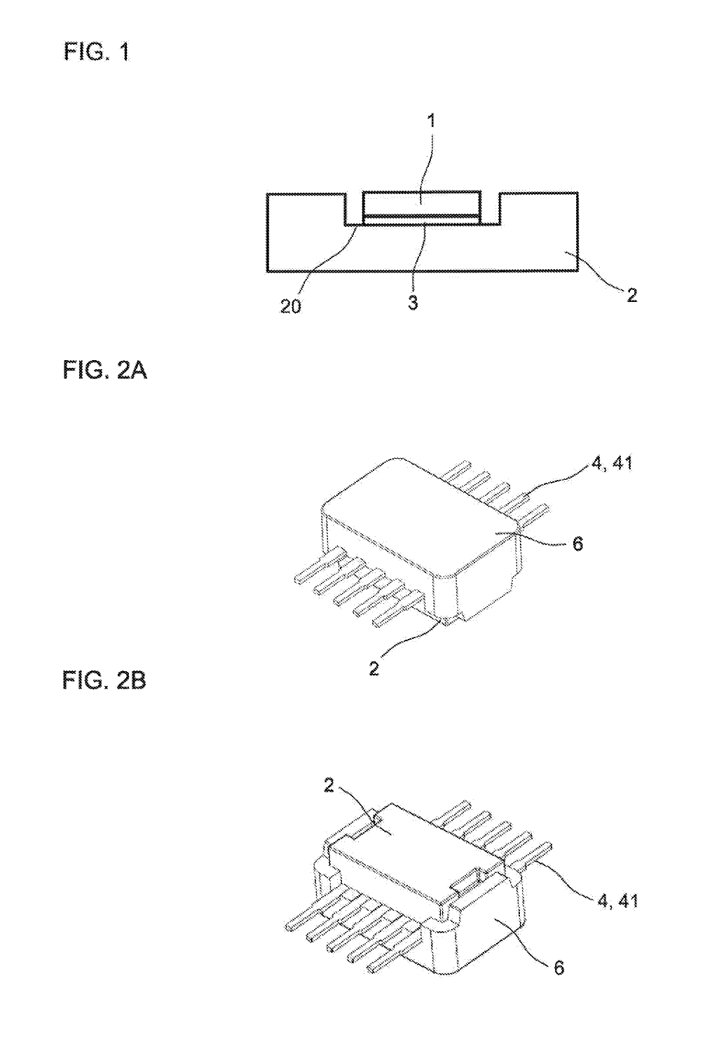

FIG. 1 shows a sensor system in accordance with one exemplary embodiment, which sensor system comprises a sensor chip 1 mounted on a mounting receptacle 20 of a ceramic housing body 2. The mounting receptacle 20 is formed by a depression of the housing body 2 on a mounting side of the housing body 2. As an alternative thereto, the mounting receptacle 20 can for example also be embodied as an elevation instead of a depression. The mounting of the sensor chip 1 on the mounting receptacle 20 of the ceramic housing body 2 is effected by means of a connection material 3, such that the sensor chip 1 is mounted directly on the housing body 2.

The sensor chip 1 is embodied as a silicon-based sensor chip which is provided and designed for example for measuring an acceleration, a rate of rotation, a pressure or a magnetic field.

The housing body 2 is shaped three-dimensionally and is embodied monolithically. In particular, in order to produce the ceramic housing body 2, a green body is produced which already has the shape of the final housing body 2 and which, in this shape, depending on material, is dried and/or subjected to binder removal and sintered.

The housing body 2 is particularly preferably produced by means of ceramic injection molding technology, as described in the general part, as a result of which freely configurable geometries and, for example, a targeted embodiment of the integrated mounting receptacle 20 for the sensor chip 1 are possible. The shape of the housing body 2 in accordance with the illustration in FIG. 1 should be understood to be purely by way of example and can have further geometrical features and surface structures or shapes which can be provided for example for receiving further electronic components, electrical contacts, a cover or for mounting the sensor system.

As an alternative to ceramic injection molding technology, the ceramic housing body 2 can for example also be produced by means of HTCC multi-layer technology. In this case, a structuring of the housing body, for example for producing the mounting receptacle 20, is effected by the stamping of ceramic sheets which are subsequently pressed for producing a green body and are sintered for completing the housing body 2.

If, by way of example, mullite is used as ceramic material for the ceramic housing body 2, the green body produced by means of injection molding technology or HTCC multi-layer technology can be sintered for example in a temperature range of 1500° C. to 1750° C. in air, depending on purity and depending on proportion of sintering additive.

In particular, the ceramic housing body 2 comprises a ceramic material having a coefficient of thermal expansion adapted to the coefficient of thermal expansion of the sensor chip 1. That means, in particular, that the coefficients of thermal expansion of the sensor chip 1. That means, in particular, that the coefficients of thermal expansion of the sensor chip 1 and of the housing body 2 deviate from one another by less than 30%, preferably by less than 20%, and particularly preferably by less than 10%. In particular, the coefficients of expansion can be adapted to one another in a temperature range of greater than or equal to −40° C. and less than or equal to 150° C., and preferably in a temperature range of greater than or equal to −50° C. and less than or equal to 200° C. It is thereby possible to ensure that at typical operating temperatures of the sensor system the coefficients of thermal expansion of the sensor chip 1 and of the housing body 2 deviate from one another as little as possible.

Mullite, that is to say aluminum silicate, has proved to be particularly advantageous as ceramic material for the ceramic housing body 2. As an alternative thereto, the ceramic material of the housing body 2 can also comprise aluminum nitride, silicon carbide or silicon nitride or consist of one or more of the ceramic materials mentioned. A suitable choice of the ceramic material with a coefficient of thermal expansion that is in the range of silicon, used as basic chip material of the sensor chip 1, advantageously makes it possible to significantly reduce or even completely avoid thermally induced mechanical stresses that could lead to corruption of the sensor signal. The monolithic embodiment of the housing body 2, which constitutes a combination of a plurality of system components in a single component in comparison with the prior art, makes it possible to significantly reduce the system complexity of the sensor system, which leads to a saving in terms of material and costs in comparison with the prior art.

As a result of the coefficients of thermal expansion of the sensor chip 1 and of the housing body 2 being adapted to one another, it is possible particularly preferably to use a rigid connection material 3, for example an epoxy resin adhesive, a glass solder or a metallic solder. The connection of the sensor chip 1 to the ceramic housing body 2 by means of a glass solder or a metallic solder is particularly advantageous. In contrast to polymers, such connection materials exhibit no ageing behavior typical of said polymers, as a result of which alterations of the sensor signal and of the mechanical connection can be avoided. Since the coefficients of thermal expansion of the sensor chip 1 and of the housing body 2 are adapted to one another, the formation of thermally induced strains in the sensor chip 1 which might affect the sensor signal can be avoided despite a fixed direct connection between the sensor chip 1 and the housing body 2 by the connection material 3.

Particularly in the case of a ceramic housing body 2 which is produced by means of ceramic injection molding technology, it is possible to achieve a very precise embodiment of the housing dimensions. As a result, simple and standardized mounting of the sensor chip 1 is possible without additional system elements, while at the same time low thermal expansion, a very high mechanical and chemical robustness and extreme long-term stability can be achieved.

The subsequent figures show further exemplary embodiments of sensor systems and show developments and modifications of the sensor system in accordance with the exemplary embodiment in FIG. 1. Therefore, the following description is restricted principally to the differences with respect to the exemplary embodiment described above.

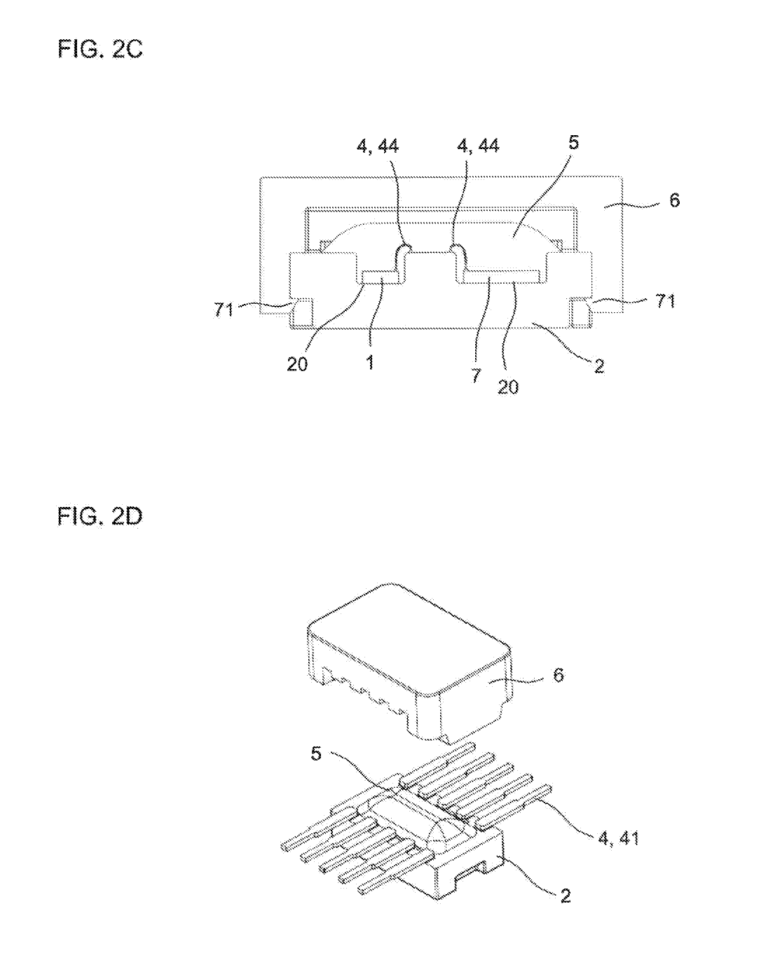

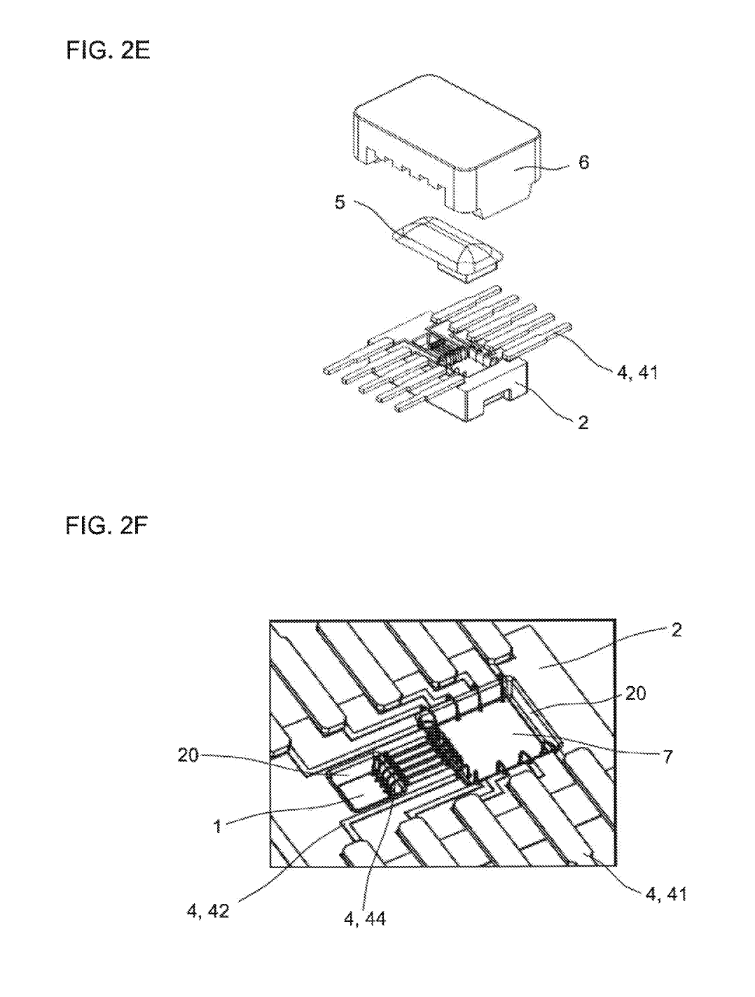

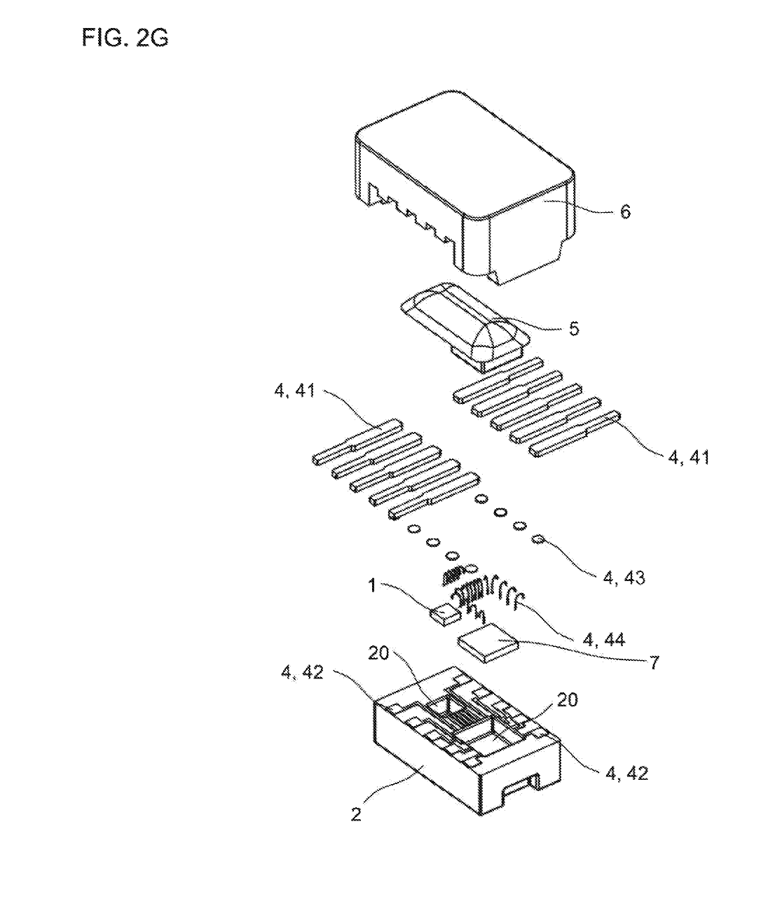

In association with FIGS. 2A to 2G, various views of a further exemplary embodiment of a sensor system are shown, which sensor system comprises a signal processing chip 7 on a further mounting receptacle 20 of the ceramic housing body 2 in addition to the sensor chip 1 on the housing body 2, wherein the mounting receptacle 20 for the sensor chip 1 and that for the signal processing chip 7 are formed in each case by depressions. As an alternative thereto, the sensor system can also comprise a plurality of sensor chips 1 and/or of signal processing chips 7. The sensor chip 1 and the signal processing chip 7 are mounted directly on the housing body 2 in each case by means of a connection material as described in association with FIG. 1 and in the general part, said connection material not being shown in the subsequent figures for the sake of clarity.

Furthermore, the sensor system shown in association with FIGS. 2A to 2G comprises electrical connections 4, a polymer potting 5 and a cover 6.

FIGS. 2A and 2B show the sensor system in a state closed by means of the cover 6, from the top side and the underside, while FIG. 2C shows a sectional illustration through the sensor system. In FIGS. 2D and 2E, the sensor system is illustrated with cover 6 having been opened, for the sake of better illustration, wherein the polymer potting 5 has additionally been lifted off in FIG. 2E. FIG. 2F shows a detail view of a sensor system opened in this way, while FIG. 2G illustrates an exploded illustration of the sensor system.

As electrical connections 4, the sensor system comprises parts of a wiring carrier 41, conductor tracks 42, solder connections 43 and bonding wires 44. Via the electrical connections 4, the sensor chip 1 can be electrically conductively connected to the signal processing chip 7 and an external electrical connection of the sensor system can furthermore be provided.

The conductor tracks 42 can be applied for example on the ceramic housing body 2 by means of metallization methods such as thick or thin film technology, for example. Advantageously, the mounting side of the housing body 2 for this purpose is embodied in a planar fashion at least regionally, such that the conductor tracks 42 can be deposited by means of cost-effective screen printing technology or sputtering technology. As an alternative thereto, given a corresponding surface topography of the housing body 2, a three-dimensional embodiment of conductor tracks can also be effected by means of pad printing or dispensing, for example.

The sensor chip 1 and the signal processing chip 7 are electrically connected to conductor tracks 42 by means of the bonding wires 44. For externally making contact with the sensor system, the wiring carrier 41 is provided, the parts of which are soldered on corresponding contact locations of the conductor tracks 42 by means of solder connections 43 and which projects from the housing body 2 closed by means of the cover 6, such that the sensor system can be electrically connected by the soldering of the wiring carrier 41. The wiring carrier 41 can be for example a rigid or flexible printed circuit board, a lead frame, or a lead frame enveloped at least partly with plastic.

As an alternative to soldering, for example soft soldering, hard soldering, glass soldering or active soldering, by means of which the wiring carrier 41 can be fixed on the conductor tracks 42 and furthermore also on parts of the housing body 2, for example, the wiring carrier 41 can also be fixed by means of adhesive bonding. Furthermore, the wiring carrier 41 can be mounted directly at the ceramic housing body 2 by means of latching, pressing or clamping into corresponding structures of the ceramic body 2. Such structures can be produced by the method described above together with the other three-dimensional housing features of the housing body. By way of example, it is also possible for the wiring carrier 41 to have cutouts through which parts of the ceramic body 2 and/or of the cover 6 extend in order to lock or fix the wiring carrier 41.

The cover 6 serves for the closure of the mounting side of the ceramic main body 2 on which the sensor chip 1 is arranged. The cover 6 can for example consist of plastic, metal or a ceramic or comprise at least one or more of the materials mentioned. In the exemplary embodiment shown, the cover 6 is produced from a plastic material, in particular. For fixing the cover 6 on the housing body 2, the housing body 2 can have cutouts into which parts of the cover 6 engage or extend through, thereby forming a mechanical locking 71 of the cover 6 on the housing body 2.

The cover 6 has a depression extending over the mounting side of the housing body 2. In the depression of the cover 6, a polymer potting 5 is arranged at least on portions of the sensor chip 1 and/or of the electrical connections 4 and/or of the signal processing chip 7 and/or of the housing body 2, which polymer potting can serve for protection or for stabilization of the covered areas or elements. As is shown in FIG. 2C, in this case the polymer potting 5 can be arranged at a distance from the cover 6, such that the depression of the cover 6 is not totally filled with the polymer. Particularly the bonding wire connections can be covered with a polymer for the stabilization thereof.

As an alternative to the exemplary embodiment shown, the pressure sensor system can also comprise only a polymer potting 5 and no cover. In this case, the polymer potting 5 can form protection of the covered parts and components with respect to the surroundings. For this purpose, the polymer potting 5 can form a covering that forms at least part of an outer side of the pressure sensor system.

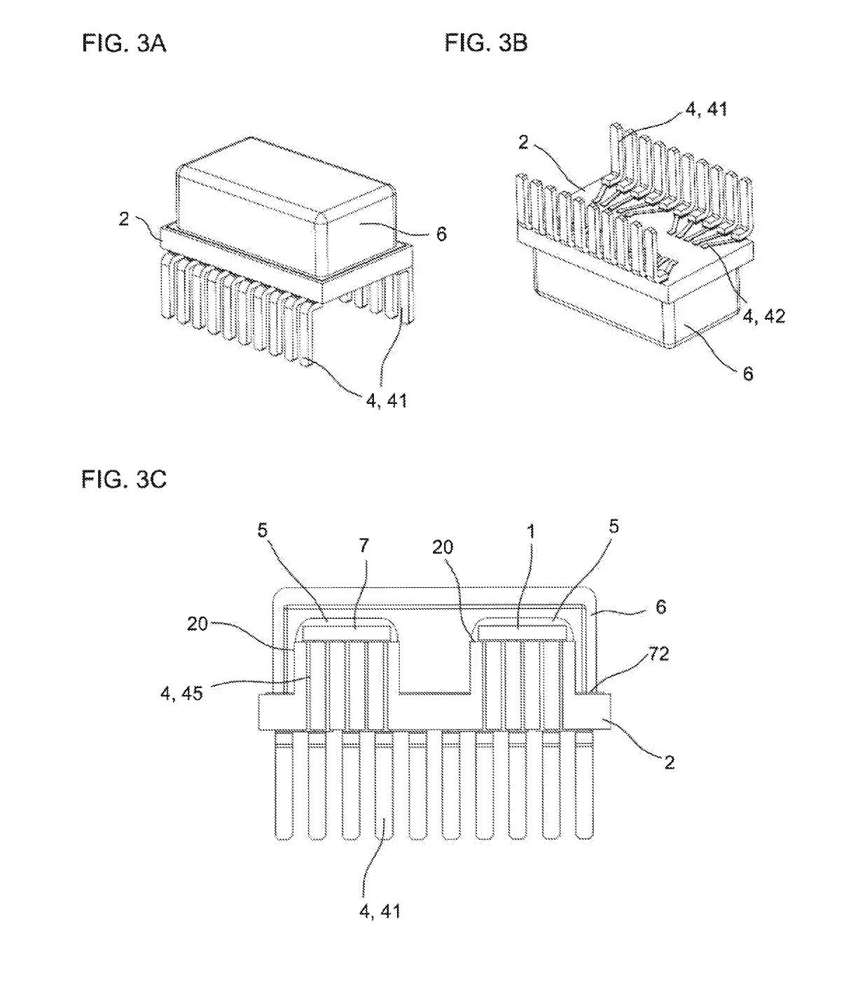

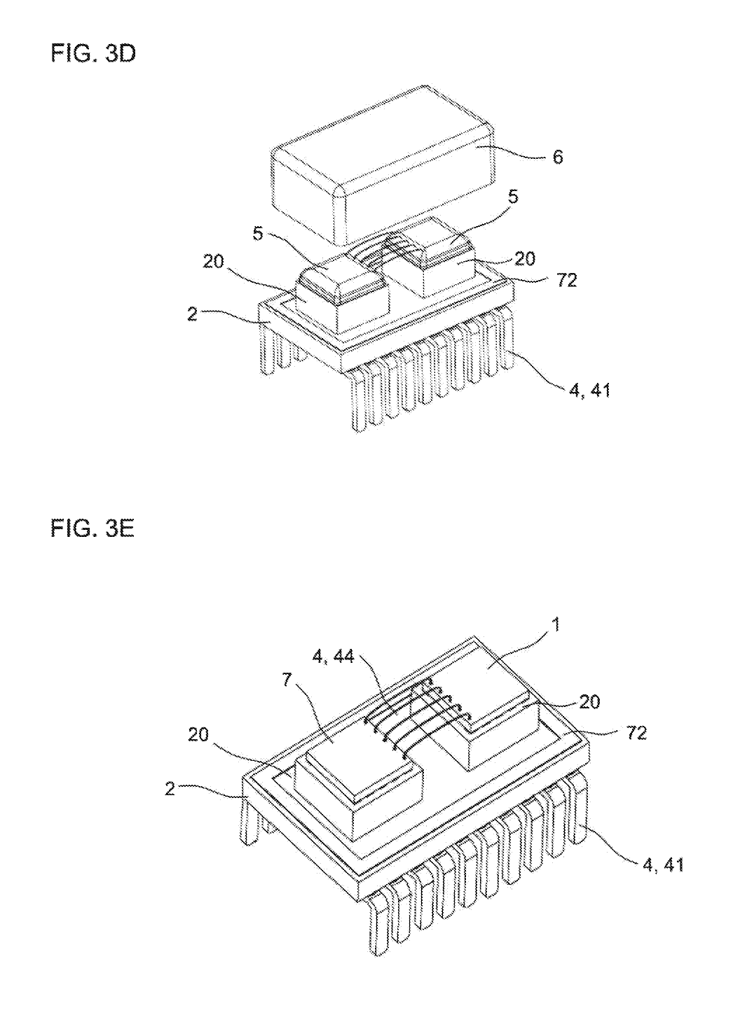

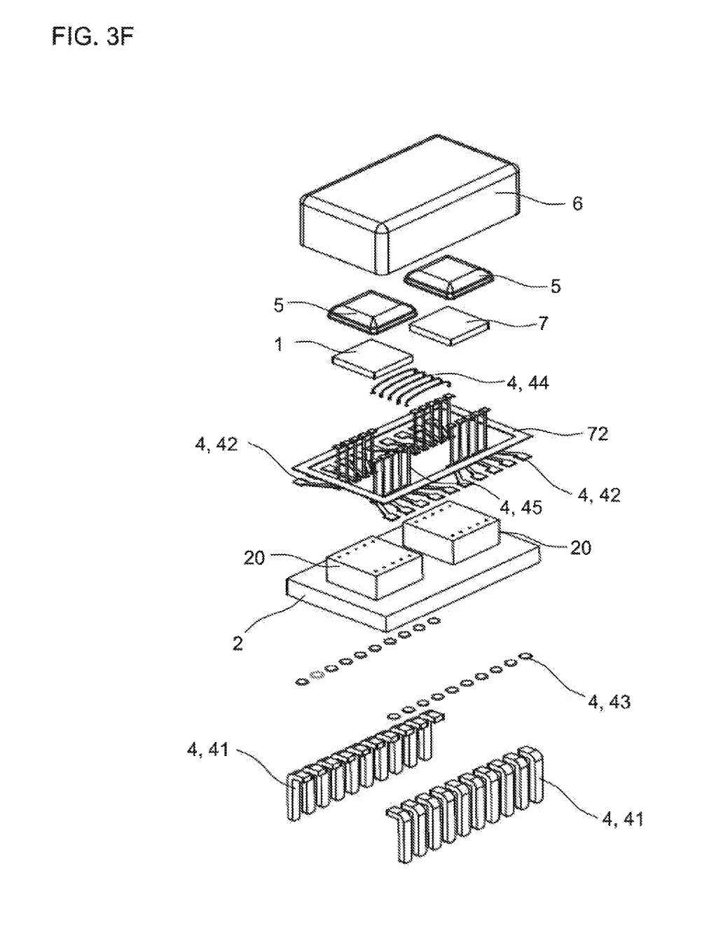

In association with FIGS. 3A to 3F, a further exemplary embodiment of a sensor system is shown, which constitutes a modification of the previous exemplary embodiment. FIGS. 3A and 3B once again show views of the top side and the underside of the sensor system, while FIG. 3C is a sectional illustration through the sensor system. FIG. 3D shows the sensor system with cover 6 having been opened, while FIG. 3E shows a detail view of the opened sensor system with polymer potting 5 having been removed. FIG. 3F shows an exploded illustration of the sensor system.

In comparison with the previous exemplary embodiment, the sensor system in accordance with the exemplary embodiment in FIGS. 3A to 3F comprises a housing body 2 with mounting receptacles 20 embodied as elevations. A sensor chip 1 and a signal processing chip 7, which are electrically contact-connected to one another via bonding wires 44, are in each case arranged on the mounting receptacles 20. In order to protect the bonding connections on the chips 1, 7, the latter are covered in each case with a dedicated polymer potting 5. In comparison with the previous exemplary embodiment, the electrical connections 4 comprise parts of a wiring carrier 41 and conductor tracks 42 on the underside of the housing body 2 facing away from the mounting side. Electrical contact is made with the chips 1, 7 by means of metallic vias 45 extending through the housing body 2 from the underside to the mounting receptacles 20.

For fixing the cover 6 on the housing body 2, a thick-film metallization 72 is provided on the housing body 2 and serves for soldering the cover 6 to the housing body 2. As an alternative thereto, the cover 6 can also be fixed on the housing body 2 by means of an adhesive, for example.

The exemplary embodiments of the sensor system as shown in the figures are not restricted to the features shown and can have further or alternative features in accordance with the embodiments in the general part.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1-15. (canceled)

16. A sensor system comprising:
a sensor chip mounted on a mounting receptacle of a housing body comprising a ceramic material, wherein the housing body comprises a non-planar three-dimensional surface topography on a mounting side on which the sensor is mounted, wherein the housing body is a monolithical structure, and wherein a coefficient of thermal expansion of the housing body deviates from the coefficient of thermal expansion of the sensor chip by less than 30% in a temperature range of greater than or equal to −40° C. and less than or equal to 150° C.

17. The sensor system according to claim 16, wherein the sensor chip is based on silicon.

18. The sensor system according to claim 16, wherein the ceramic material comprises mullite.

19. The sensor system according to claim 16, wherein the ceramic material comprises aluminum nitride, silicon carbide and/or silicon nitride.

20. The sensor system according to claim 16, wherein the ceramic material consists of one or more selected from mullite, aluminum nitride, silicon carbide and/or silicon nitride.

21. The sensor system according to claim 16, wherein the coefficients of thermal expansion of the housing body and of the sensor chip deviate from one another by less than 10%, in a temperature range of greater than or equal to −50° C. and less than or equal to 200° C.

22. The sensor system according to claim 16, wherein the housing body has a non-planar three-dimensional surface topography on the mounting side and the mounting receptacle is formed by an elevation or a depression of the housing body.

23. The sensor system according to claim 16, wherein a signal processing chip is mounted on a further mounting receptacle of the housing body.

24. The sensor system according to claim 16, wherein the sensor chip is mounted directly on the mounting receptacle by a rigid connection material formed by a glass solder, a metallic solder, or an epoxy resin adhesive.

25. The sensor system according to claim 16, wherein the sensor chip is mounted directly on the mounting receptacle by a flexible connection material formed by a silicone adhesive.

26. The sensor system according to claim 16, wherein the housing body is shaped three-dimensionally and embodied monolithically by a ceramic injection molding method or by an HTCC multi layer method.

27. The sensor system according to claim 16, wherein the sensor system comprises electrical connections on and/or in the housing body for the electrical connection at least of the sensor chip, the electrical connections comprising one or more of the following elements:
wiring carriers, conductor tracks, bonding wires, and metallic vias.

28. The sensor system according to claim 16, wherein the sensor chip is electrically contacted by bonding wire connections covered with a polymer potting.

29. The sensor system according to claim 16, wherein the sensor system comprises a cover fixed on the housing body above the sensor chip.

30. The sensor system according to claim 29, wherein the cover is adhesively bonded, soldered or fixed by a mechanical locking on the housing body.

31. A method of forming a sensor system, the method comprising:
providing a sensor chip;
forming a housing body having a monolithical structure and comprising a non-planar three-dimensional surface topography on a mounting side using a ceramic injection molding method or by an HTCC multi-layer method; and
mounting the sensor chip over the mounting side of the housing body, wherein the coefficient of thermal expansion of the housing body deviates from the coefficient of thermal expansion of the sensor chip by less than 30% in a temperature range of greater than or equal to −40° C. and less than or equal to 150° C.

32. The method of claim 31, wherein the housing body comprises mullite.

33. The method of claim 31, wherein forming the housing body comprises sintering at 1500° C. to 1750° C. in air.

34. The method of claim 31, wherein forming the housing body comprises fixing a cover on the housing body above the sensor chip.

35. The method of claim 34, wherein the cover is adhesively bonded, soldered or fixed by a mechanical locking on the housing body.
